(19) United States
(12) Patent Application Publication
(10) Pub. No.: US 2024/0178212 A1
(43) Pub. Date: May 30, 2024

(54) SEMICONDUCTOR DEVICE AND ELECTRONIC DEVICE

(71) Applicant: Kioxia Corporation, Tokyo (JP)

(72) Inventors: Ken MURAMATSU, Yokohama (JP); Shinya SHIMIZU, Ota (JP)

(73) Assignee: Kioxia Corporation, Tokyo (JP)

(21) Appl. No.: 18/435,091

(22) Filed: Feb. 7, 2024

Related U.S. Application Data
(63) Continuation of application No. PCT/JP2022/001343, filed on Jan. 17, 2022.

(30) Foreign Application Priority Data
Aug. 25, 2021 (JP) 2021-137286

(51) Int. Cl. H01L 25/18; H01L 23/00; H01L 23/31; H01L 23/367; H01L 23/552; H10B 80/00

(52) U.S. Cl. CPC H01L 25/18; H01L 23/3128; H01L 23/367; H01L 23/3675; H01L 23/552; H01L 24/48; H01L 24/49; H10B 80/00; H01L 2224/48091; H01L 2224/48106; H01L 2224/48227; H01L 2224/49176

(57) ABSTRACT

According to one embodiment, a semiconductor device includes: a substrate; a controller disposed on the substrate; a nonvolatile memory disposed on the substrate to be separated from the controller; a first heat sink disposed in contact with an upper surface of the controller; a second heat sink disposed in contact with an upper surface of the nonvolatile memory; and a first resin sealing body sealing the controller, the nonvolatile memory, the first heat sink, and the second heat sink. The first heat sink and the second heat sink are exposed on at least one surface selected from the group consisting of an upper surface and a side surface of the first resin sealing body.

### CROSS REFERENCE TO RELATED APPLICATIONS

This is a continuation application (CA) of PCT Application No. PCT/JP2022/001343, filed on Jan. 17, 2022, which claims priority to Japan Patent Application No. P2021-137286 filed on Aug. 25, 2021, and is based upon and claims the benefit of priority from prior Japanese Patent Application No. P2021-137286 filed on Aug. 25, 2021 and PCT Application No. PCT/JP2022/001343, filed on Jan. 17, 2022, the entire contents of each of which are incorporated herein by reference.

### FIELD

Embodiments described herein relate generally to a semiconductor device and an electronic device.

### BACKGROUND

In recent years, general semiconductor devices have been used in the form of packages molded with resin. Such packages molded by resin are generally made with a mixture of an epoxy resin and silica, which has a low coefficient of thermal conductivity, and may become a hindrance to thermal dissipation.

### BRIEF DESCRIPTION OF THE DRAWINGS

FIG. 1 is a block diagram illustrating an example of a configuration of a semiconductor device according to a first embodiment.

FIG. 2A is a cross-sectional diagram illustrating a semiconductor device according to the first embodiment.

FIG. 2B is a top view diagram of illustrating the semiconductor device according to the first embodiment.

FIG. 3A is a cross-sectional diagram illustrating a semiconductor device according to a second embodiment.

FIG. 3B is a top view diagram of illustrating the semiconductor device according to the second embodiment.

FIG. 4A is a cross-sectional diagram of a semiconductor device according to a modified example of the second embodiment.

FIG. 4B is a top view diagram of the semiconductor device according to the modified example of the second embodiment.

FIG. 5A is a cross-sectional diagram illustrating a semiconductor device according to a third embodiment.

FIG. 5B is a top view diagram of illustrating the semiconductor device according to the third embodiment.

FIG. 6A is a cross-sectional diagram of a semiconductor device according to a modified example of the third embodiment.

FIG. 6B is a top view diagram of the semiconductor device according to the modified example of the third embodiment.

FIG. 7A is a cross-sectional diagram illustrating a semiconductor device according to a fourth embodiment.

FIG. 7B is a top view diagram of illustrating the semiconductor device according to the fourth embodiment.

FIG 8A is a cross-sectional diagram of a semiconductor device according to a modified example of the fourth embodiment.

FIG. 8B is a top view diagram of the semiconductor device according to the modified example of the fourth embodiment.

FIG. 9A is a cross-sectional diagram illustrating a semiconductor device according to a fifth embodiment.

FIG. 9B is a top view diagram of illustrating the semiconductor device according to the fifth embodiment.

FIG. 10A is a cross-sectional diagram of a semiconductor device according to a modified example of the fifth embodiment.

FIG. 10B is a top view diagram of the semiconductor device according to the modified example of the fifth embodiment.

FIG. 11A is a cross-sectional diagram illustrating a semiconductor device according to a sixth embodiment.

FIG. 11B is a top view diagram of illustrating the semiconductor device according to the sixth embodiment.

FIG. 12 is a diagram illustrating an example of an electronic device in which the semiconductor device according to embodiments is mounted.

FIG. 13 is a block diagram illustrating a circuit substrate of the electronic device.

FIG. 14 is a diagram illustrating an example of an electronic device in which the semiconductor device according to embodiments is mounted.

FIG. 15 is a diagram illustrating an example of an electronic device in which the semiconductor device according to embodiments is mounted.

FIG. 16 is a diagram illustrating an example of an electronic device in which the semiconductor device according to embodiments is mounted.

### DETAILED DESCRIPTION

Next, certain embodiments will now be explained with reference to drawings. In the description of the following drawings to be explained, the identical or similar reference sign is attached to the identical or similar part. However, the drawings are merely schematic.

Moreover, the embodiments described hereinafter merely exemplify devices and methods for materializing the technical idea; and the embodiments do not specify the material, shape, structure, placement, etc. of each component. The embodiments may be changed without departing from the spirit or scope of claims.

Certain embodiments provide a semiconductor device having improved thermal dispersion characteristics.

According to one embodiment, a semiconductor device includes: a substrate; a controller disposed on the substrate; a nonvolatile memory disposed on the substrate to be separated from the controller; a first heat sink disposed in contact with an upper surface of the controller; a second heat sink disposed in contact with an upper surface of the nonvolatile memory; a first resin sealing body sealing the controller, the nonvolatile memory, the first heat sink, and the second heat sink. The first heat sink and the second heat sink are exposed on at least one surface selected from the group consisting of an upper surface and a side surface of the first resin sealing body.

### FIRST EMBODIMENT

### Configuration of Semiconductor Device

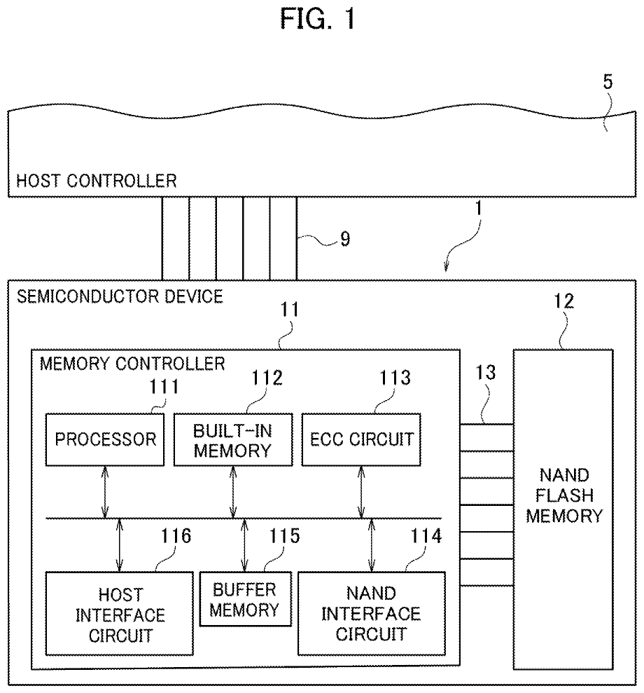

A semiconductor device 1 according to a first embodiment will now be described. FIG. 1 is a block diagram illustrating the semiconductor device 1 according to the first embodiment. As illustrated in FIG. 1, the semiconductor device 1 includes a memory controller 11, which is an example of a controller, and a NAND flash memory 12, which is an example of a nonvolatile memory. The memory controller 11 is connected to the NAND flash memory 12 through a NAND interface 13. The nonvolatile memory is not limited to a nonvolatile semiconductor memory such as the NAND flash memory 12, but may also be any memory capable of 20 storing data, such as Resistive Random Access Memory (ReRAM) or Ferroelectric Random Access Memory (FeRAM). In the following description, the NAND flash memory 12, which is an example of nonvolatile memory, will be described.

The memory controller 11 includes a processor 111, a built-in memory 112, an Error Checking and Correction (ECC) circuit 113, a NAND interface circuit 114, a buffer memory 115, and a host interface circuit 116.

The processor 111 is an integrated circuit configured to receive an instruction from the host controller 5 through a plurality of signal lines 9 and to control the NAND flash memory 12 on the basis of the received instruction.

The built-in memory 112 is a semiconductor memory, such as Dynamic Random Access Memory (DRAM), for example, and is used as a work area of the processor 111. In addition, the built-in memory 112 may store firmware, various kinds of management tables, and the like, for managing the NAND flash memory 12.

The ECC circuit 113 executes error detection and error correction processing. Specifically, when data is written, an ECC code is generated for each set including a certain number of pieces of data on the basis of data received from the host controller 5. When data is read out, ECC decoding is executed on the basis of the ECC code to detect the presence or absence of an error. Moreover, when an error is detected, a bit location where the error is detected is specified to correct the error.

The NAND interface circuit 114 is connected to the NAND flash memory 12 through the NAND interface 13 and manages communications with the NAND flash memory 12. The NAND interface circuit 114 transmits, for example, a command CMD, an address ADD, and write data to the NAND flash memory 12 in accordance with an instruction from the processor 111. The NAND interface circuit 114 also receives read data from the NAND flash memory 12.

The buffer memory 115 temporarily stores data and the like received by the memory controller 11 from the NAND flash memory 12 and the host controller 5. The buffer memory 115 is also used, for example, as a storage area for temporarily stores read data from the NAND flash memory 12, an operation result on read data, and the like.

The host interface circuit 116 is connected to the host controller 5 through the plurality of signal lines 9 and manages communications with the host controller 5. The host interface circuit 116 transfers respectively, for example, an instruction and data received from the host controller 5 to the processor 111 and the buffer memory 115.

### Configuration of Package Structure of Semiconductor Device

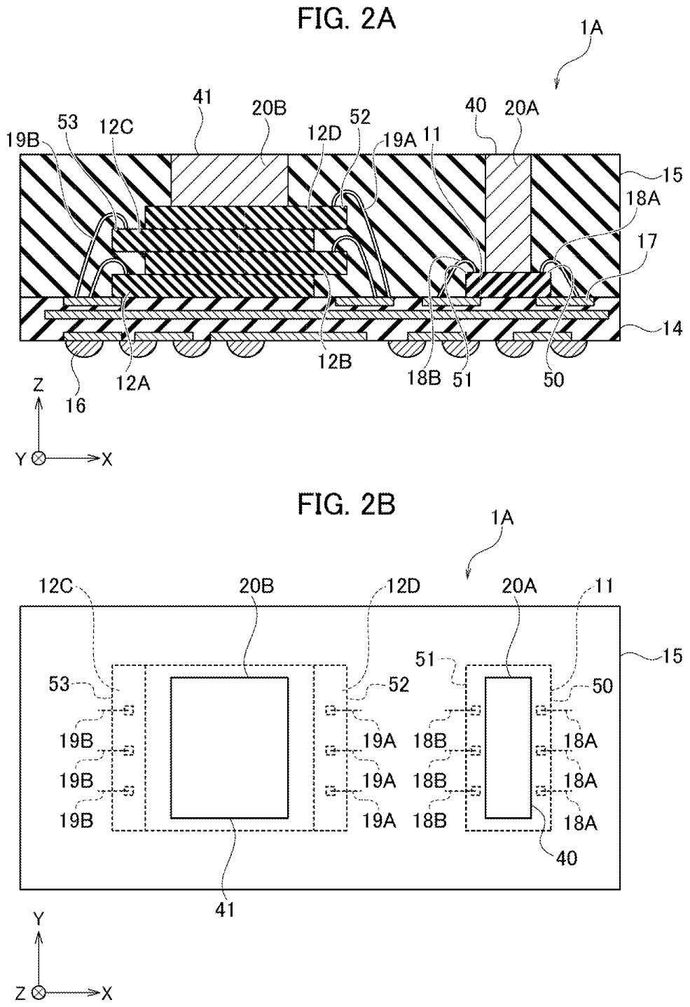

Next, a package structure of a semiconductor device 1A according to the first embodiment will now be described. FIG. 2A is a cross-sectional diagram of the semiconductor device 1A according to the first embodiment. FIG. 2B is a top view diagram of the semiconductor device 1A according to the first embodiment. In the following description, the X direction indicates a longitudinal direction of the semiconductor device 1A, the Y direction indicates a non-longitudinal direction of the semiconductor device 1A orthogonal perpendicularly to the X direction, and the Z direction illustrates a direction perpendicular to the X-Y plane.

As illustrated in FIG. 2A, the semiconductor device 1A includes a memory controller 11, a NAND flash memory 12 (NAND flash memories 12A, 12B, 12C, 12D), a substrate 14, a first resin sealing body 15, a bonding wire (bonding wires 18A, 18B, 19A, 19B), a solder ball(s) 16, a first heat sink 20A, and a second heat sink 20B.

The substrate 14 includes a multilayered wiring The substrate 14 includes a wiring(s) 17. In substrate. the substrate 14, the solder ball 16 and the bonding wire (18A, 18B, 19A, 19B) are electrically connected to each other through the wiring 17.

The bonding wire includes a first bonding wire 18A, a second bonding wire 18B, a third bonding wire 19A, and a fourth bonding wire 19B.

The memory controller 11 is disposed on the substrate 14. The memory controller 11 is electrically connected to the wiring 17 through the first and second bonding wires (18A, 18B).

As illustrated in FIGS. 2A and 2B, the memory controller 11 includes a first one end 50 and a first other end 51 opposite to the first one end 50.

Specifically, as illustrated in FIG. 2B, on the memory controller 11, the first bonding wire 18A is electrically connected to the first one end 50. Moreover, the second bonding wire 18B is electrically connected to the first other end 51. The memory controller 11 is electrically connected to the wiring 17 through the first and second bonding wires (18A, 18B).

The NAND flash memory 12 (12A, 12B, 12C, 12D) is disposed on the substrate 14. The NAND flash memory 12 (12A, 12B, 12C, 12D) is disposed on the substrate 14 to be separated from the memory controller 11. The NAND flash memory 12 (12A, 12B, 12C, 12D) is electrically connected to the wiring 17 through the third and fourth bonding wires (19A, 19B).

As illustrated in FIGS. 2A and 2B, the NAND flash memory 12 (12A, 12B, 12C, 12D) includes a second one end 52 and a second other end 53 opposite to the second one end 52.

Specifically, as illustrated in FIG. 2B, on the NAND flash memory 12 (12A, 12B, 12C, 12D), the third bonding wire 19A is electrically connected to the second one end 52. Moreover, the fourth bonding wire 19B is electrically connected to the second other end 53.

The first resin sealing body 15 seals the memory controller 11, the NAND flash memory 12 (12A, 12B, 12C, 12D), the first to fourth bonding wires (18A, 18B, 19A, 19B), the first heat sink 20A, and the second heat sink 20B. The first resin sealing bodies 15 may be, for example, a mixture of an epoxy resin and silica.

The first heat sink 20A and the second heat sink 20B are formed of, for example, a metal having a high coefficient of thermal conductivity. Specifically, copper (Cu), aluminum (Al), silver (Ag), gold (Au), or the like can be applied thereto.

The first heat sink 20A is disposed in contact with an upper surface of the memory controller 11. Namely, heat generated from the memory controller 11 is dissipated mainly from the first heat sink 20A.

An upper surface 40 of the first heat sink 20A is exposed flush with an upper surface of the first resin sealing body 15, as illustrated in FIG. 2B.

As illustrated in FIGS. 2A and 2B, the first heat sink 20A is disposed between the first bonding wire 18A and the second bonding wire 18B on the memory controller 11 in planar view. Namely, the first and second bonding wires (18A, 18B) are disposed outside the first heat sink 20A in planar view. As illustrated in FIG. 2A, a thickness of the first heat sink 20A may be thicker than a thickness of the second heat sink 20B, in the Z direction.

The second heat sink 20B is disposed in contact with an upper surface of the NAND flash memory 12. Therefore, the second heat sink 20B has excellent thermal conductivity with respect to the NAND flash memory 12. Specifically, the second heat sink 20B is disposed in contact with an upper surface of the uppermost NAND flash memory 12D among the stacked NAND flash memories 12 (12A, 12B, 12C, 12D). Therefore, the second heat sink 20B has excellent thermal conductivity with respect to the NAND flash memory 12D. Namely, the heat generated from the NAND flash memory 12 (12A, 12B, 12C, 12D) is dissipated mainly from the second heat sink 20B.

An upper surface 41 of the second heat sink 20B is exposed flush with the upper surface of the first resin sealing body 15, as illustrated in FIG. 2B. In addition, the exposed area of the second heat sink 20B may be larger than the exposed area of the first heat sink 20A. In the following description, a main surface on a plus side in the Z direction is referred to as an upper surface.

As illustrated in FIGS. 2A and 2B, the second heat sink 20B is disposed between the third bonding wire 19A electrically connected to the second one end 52 side and the fourth bonding wire 19B electrically connected to the second other end 53 side on the NAND flash memory 12 in planar view. Namely, the third and fourth bonding wires (19A, 19B) are disposed outside the second heat sink 20B in planar view. In addition, the number of the NAND flash memories 12 may not be limited to four, but may be three or less, or five or more.

The solder balls 16 are used as input/output pins for the semiconductor device 1A. Specifically, the semiconductor device 1A can supply a power supply voltage and can perform input/output of signals, through the solder balls 16.

### Advantageous Effects of First Embodiment

In accordance with the semiconductor device according to the first embodiment, the heat generated from the memory controller and the NAND flash memory can be appropriately dissipated respectively to the first heat sink and the second heat sink, and thereby thermal dispersion characteristics can be improved.

### SECOND EMBODIMENT

### Configuration of Package Structure of Semiconductor Device

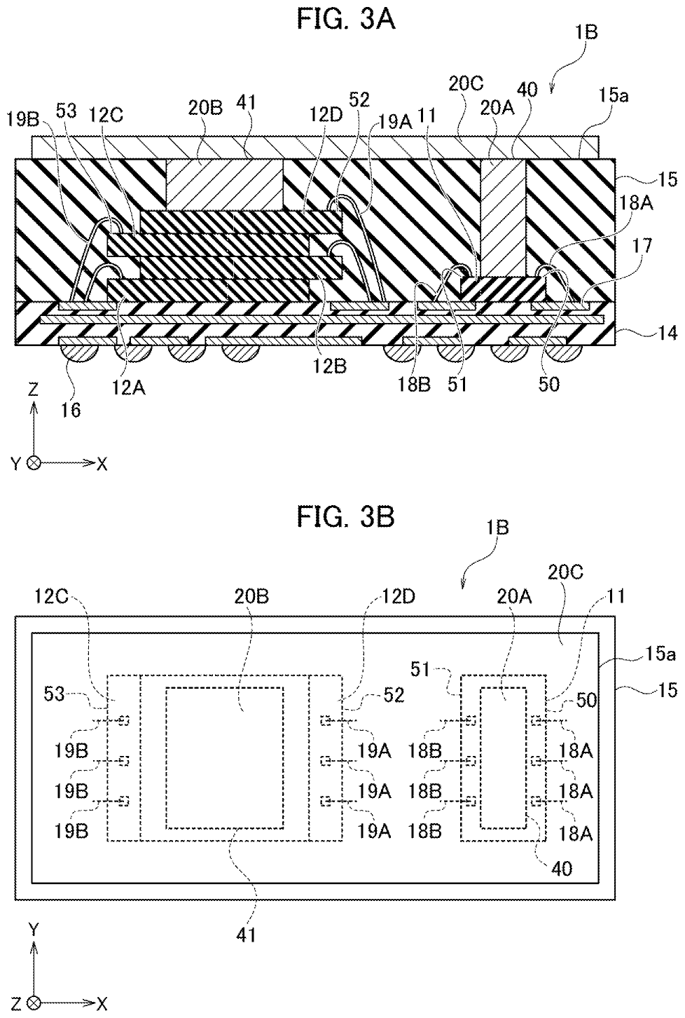

FIG. 3A is a cross-sectional diagram illustrating a semiconductor device 1B according to a second embodiment. FIG. 3B is a top view diagram illustrating the semiconductor device 1B according to the second embodiment.

As illustrated in FIG. 3A, the semiconductor device 1B according to the second embodiment further includes a first external heat sink 20C configured to cover an upper surface 15a of the first resin sealing body 15 with respect to the semiconductor device 1A according to the first embodiment. In the following description, the heat sink disposed outside the first resin sealing body 15 is referred to as an external heat sink (e.g., a first external heat sink 20C). Since the rest of configuration is identical with that of the first embodiment, the duplicated description is omitted.

The first external heat sink 20C is formed of, for example, a metal having a high coefficient of thermal conductivity. Specifically, copper (Cu), aluminum (Al), silver (Ag), gold (Au), or the like can be applied thereto.

As illustrated in FIG. 3A, the first external heat sink 20C is disposed in contact with the upper surface 15a of the first resin sealing body 15. The first external heat sink 20C is disposed in contact with the upper surface 40 of the first heat sink 20A and the upper surface 41 of the second heat sink 20B, each exposed on the upper surface 15a of the first resin sealing body 15. Namely, the heat generated from the memory controller 11 is dissipated mainly from the first heat sink 20A. Moreover, the heat generated from the NAND flash memory 12 (12A, 12B, 12C, 12D) is dissipated mainly from the second heat sink 20B. Furthermore, the heat from the first heat sink 20A and the second heat sink 20B is dissipated mainly from the first external heat sink 20C.

As illustrated in FIG. 3B, the first external heat sink 20C is disposed to cover the upper surfaces (40, 41) of the first heat sink 20A and the second heat sink 20B. An area of the first external heat sink 20C is disposed smaller than an area of the first resin sealing body 15 in planar view.

### Advantageous Effects of Second Embodiment

In accordance with the semiconductor device according to the second embodiment, the heat generated from the memory controller and the NAND flash memory can be appropriately dissipated respectively to the first heat sink and the second heat sink, and thereby thermal dispersion characteristics can be improved. Moreover, the heat from the first heat sink and the second heat sink can be appropriately dissipated to the first external heat sink, and thereby thermal dispersion characteristics can be further improved.

### MODIFIED EXAMPLE OF SECOND EMBODIMENT

### Configuration of Package Structure of Semiconductor Device

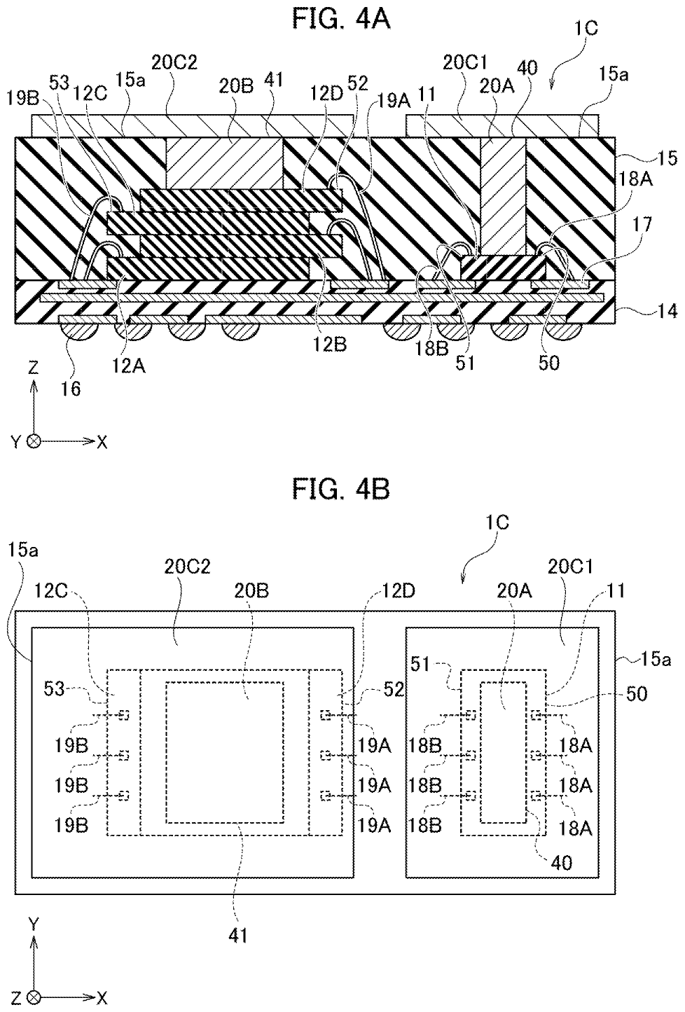

FIG. 4A is a cross-sectional diagram illustrating a semiconductor device 1C according to a modified example of the second embodiment. FIG. 4B is a top view diagram illustrating the semiconductor device 1C according to the modified example of the second embodiment.

As illustrated in FIG. 4A, the semiconductor device 1C according to the modified example of the second embodiment includes a second external heat sink 20C1 and a third external heat sink 20C2 configured to cover the upper surface 15a of the first resin sealing body 15, in contrast to the first external heat sink 20C in the semiconductor device 1B according to the second embodiment. Since the rest of configuration is identical with that of the first embodiment, the duplicated description is omitted.

The second external heat sink 20C1 and the third external heat sink 20C2 are formed of, for example, a metal having a high coefficient of thermal conductivity. Specifically, copper (Cu), aluminum (Al), silver (Ag), gold (Au), or the like can be applied the metal.

As illustrated in FIG. 4A, the second external heat sink 20C1 is disposed in contact with the upper surface 15a of the first resin sealing body 15. The second external heat sink 20C1 is disposed in contact with the upper surface 40 of the first heat sink 20A exposed on the upper surface 15a of the first resin sealing body 15. Namely, the heat generated from the memory controller 11 is dissipated mainly from the first heat sink 20A. Specifically, the heat from the first heat sink 20A is dissipated mainly from the second external heat sink 20C1.

As illustrated in FIG. 4B, the second external heat sink 20C1 is disposed to cover the exposed upper surface 40 of the first heat sink 20A.

As illustrated in FIG. 4A, the third external heat sink 20C2 is disposed in contact with the upper surface 15a of the first resin sealing body 15. The third external heat sink 20C2 is disposed in contact with the second heat sink 20B exposed on the upper surface 15a of the first resin sealing body 15.

As illustrated in FIG. 4B, the third external heat sink 20C2 is disposed to cover the exposed upper surface 41 of the second heat sink 20B. Namely, the third external heat sink 20C2 is disposed to be separated from the second external heat sink 20C1. Namely, the heat generated from the memory controller 11 is dissipated mainly from the first heat sink 20A. Moreover, the heat generated from the NAND flash memory 12 (12A, 12B, 12C, 12D) is dissipated mainly from the second heat sink 20B. That is, the heat generated from the memory controller and the NAND flash memory is dissipated to be separated into the second external heat sink 20C1 and the third external heat sink 20C2. An area of the third external heat sink 20C2 may be disposed larger than an area of the second external heat sink 20C1 in planar view.

### Advantageous Effects of Modified Example of Second Embodiment

In accordance with the semiconductor device according to the modified example of the second embodiment, the heat generated from the memory controller and the NAND flash memory can be appropriately dissipated respectively to the first heat sink and the second heat sink, and thereby thermal dispersion characteristics can be improved.

Moreover, in accordance with the semiconductor device according to the modified example of the second embodiment, since the second external heat sink and the third external heat sink are provided, the heat generated from the memory controller and the NAND flash memory can be dissipated to be separated, and thereby thermal dispersion characteristics can be further improved.

### THIRD EMBODIMENT

### Configuration of Package Structure of Semiconductor Device

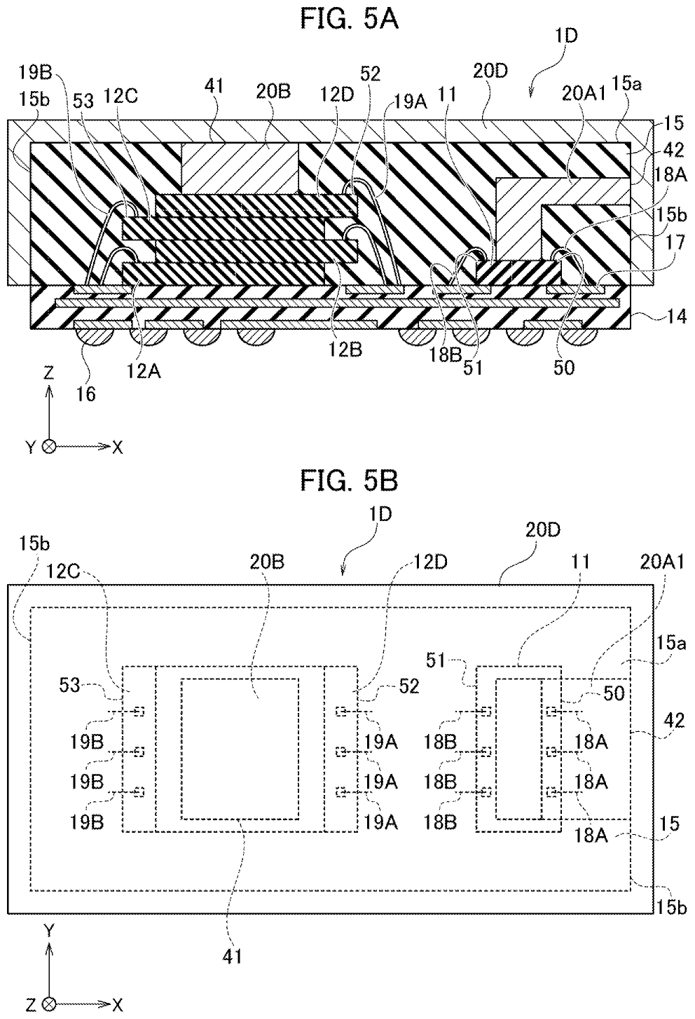

FIG. 5A is a cross-sectional diagram illustrating a semiconductor device 1D according a third embodiment. FIG. 5B is a top view diagram illustrating the semiconductor device 1D according to the third embodiment.

As illustrated in FIG. 5A, the semiconductor device 1D according to the third embodiment includes a third heat sink 20A1, which is an example of the first heat sink, in contrast to the first heat sink 20A in the semiconductor device 1A according to the first embodiment. The semiconductor device 1D further includes a fourth external heat sink 20D configured to cover the upper surface 15a and the side surface 15b of the first resin sealing body 15. Since the rest of configuration is identical with that of the first embodiment, the duplicated description is omitted.

The third heat sink 20A1 and the fourth external heat sink 20D are formed of, for example, a metal having a high coefficient of thermal conductivity. Specifically, copper (Cu), aluminum (Al), silver (Ag), gold (Au), or the like can be applied the metal.

The third heat sink 20A1 is disposed in contact with the upper surface of the memory controller 11. Namely, the heat generated from the memory controller 11 is dissipated mainly from the third heat sink 20A1. Moreover, the third heat sink 20A1 includes a portion extending in the Z direction and a portion extending in the X direction. Alternatively, the portion extending in the X direction may extend in the Y direction.

In the portion extending in the X direction of the third heat sink 20A1, as illustrated in FIGS. 5A and 5B, a side surface 42 of the third heat sink 20A1 is exposed in the X direction from the first resin sealing body 15. Alternatively, the side surface 42 of the third heat sink 20A1 may be exposed in the Y direction.

As illustrated in FIGS. 5A and 5B, the portion extending in the Z direction of the third heat sink 20A1 is disposed between the first bonding wire 18A and the second bonding wire 18B on the memory controller 11 in planar view. Namely, the first and second bonding wires (18A, 18B) are disposed outside the third heat sink 20A1 in planar view. in addition, a thickness of the third heat sink 20A1 may be thicker than a thickness of the second heat sink 20B in the Z direction, as illustrated in FIG. 5A.

As illustrated in FIG. 5A, the fourth external heat sink 20D is disposed in contact with the upper surface 15a and side surfaces 15b of the first resin sealing body 15. Moreover, the fourth external heat sink 20D is disposed in contact with the side surface 42 of the third heat sink 20A1 and the upper surface 41 of the second heat sink 20B. Namely, heat from the third heat sink 20A1 and the second heat sink 20B is dissipated mainly from the fourth external heat sink 20D.

As illustrated in FIG. 5B, the fourth external heat sink 20D is disposed to cover the side surface 42 of the third heat sink 20A1 and the upper surface 41 of the second heat sink 20B. An area of the third heat sink 20A1 may be disposed larger than an area of the second heat sink 20B in planar view.

### Advantageous Effects of Third Embodiment

In accordance with the semiconductor device according to the third embodiment, the heat generated from the memory controller and the NAND flash memory can be appropriately dissipated respectively to the third heat sink and the second heat sink, and thereby thermal dispersion characteristics can be improved. Moreover, the heat from the third heat sink and the second heat sink can be appropriately dissipated to the fourth external heat sink, and thereby thermal dispersion characteristics can be further improved.

### MODIFIED EXAMPLE OF THIRD EMBODIMENT

### Configuration of Package Structure of Semiconductor Device

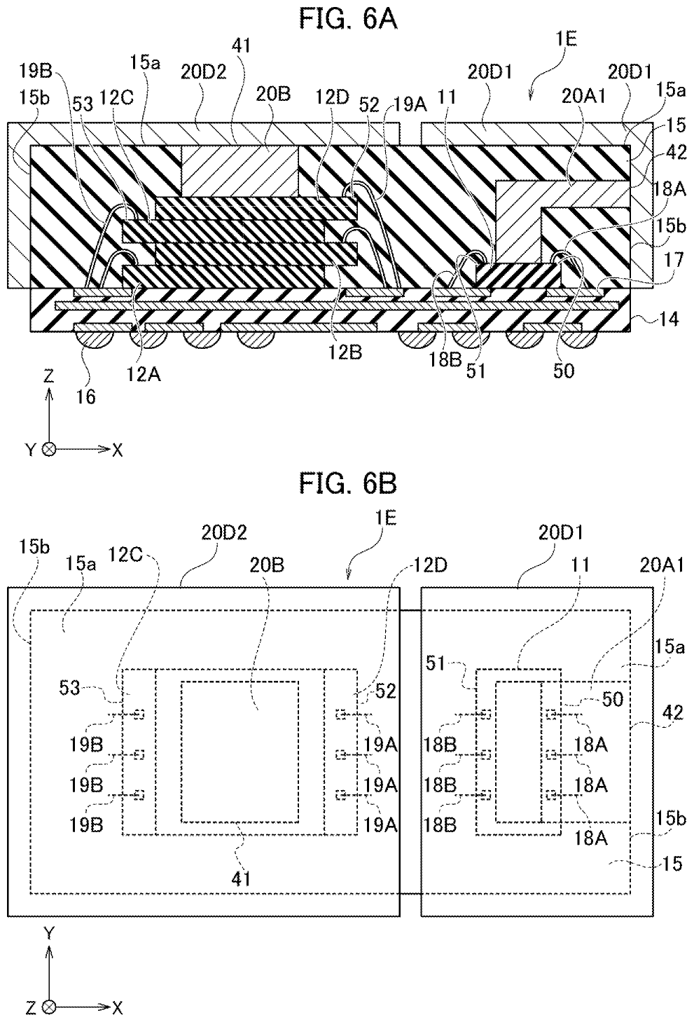

FIG. 6A is a cross-sectional diagram illustrating a semiconductor device 1E according to a modified example of the third embodiment. FIG. 6B is a top view diagram illustrating the semiconductor device 1E according to the modified example of the third embodiment.

As illustrated in FIG. 6A, the semiconductor device 1E according to the modified example of the third embodiment includes a fifth external heat sink 20D1 and a sixth external heat sink 20D2 configured to cover the upper surface 15a and the side surfaces 15b of the first resin sealing body 15, in contrast to the fourth external heat sink 20D in the semiconductor device 1D according to the third embodiment. Since the rest of configuration is identical with that of the third embodiment, the duplicated description is omitted.

The fifth external heat sink 20D1 and the sixth external heat sink 20D2 are formed of, for example, a metal having a high coefficient of thermal conductivity. Specifically, copper (Cu), aluminum (Al), silver (Ag), gold (Au), or the like can be applied the metal.

As illustrated in FIG. 6A, the fifth external heat sink 20D1 is disposed in contact with the upper surface 15a and the side surface 15b of the first resin sealing body 15. The fifth external heat sink 20D1 is disposed in contact with the side surface 42 of the third heat sink 20A1. Namely, the heat from the third heat sink 20A1 is dissipated mainly from the fifth external heat sink 20D1.

As illustrated in FIG. 6A, the sixth external heat sink 20D2 is disposed in contact with the upper surface 15a and the side surface 15b of the first resin sealing body 15. The sixth external heat sink 20D2 is disposed in contact with the upper surface 41 of the second heat sink 20B.

As illustrated in FIGS. 6A and 6B, the fifth external heat sink 20D1 is disposed to cover the exposed side surface 42 of the third heat sink 20A1.

As illustrated in FIG. 6B, the sixth external heat sink 20D2 is disposed to cover the exposed upper surface 41 of the second heat sink 20B. Namely, the sixth external heat sink 20D2 is disposed to be separated from the fifth external heat sink 20D1. Namely, the heat from the second heat sink 20B is dissipated mainly from the sixth external heat sink 20D2. An area of the sixth external heat sink 20D2 may be disposed larger than an area of the fifth external heat sink 20D1 in planar view.

### Advantageous Effects of Modified Example of Third Embodiment

In accordance with the semiconductor device according to the modified example of the third embodiment, the heat generated from the memory controller and the NAND flash memory can be appropriately dissipated respectively to the third heat sink and the second heat sink, and thereby thermal dispersion characteristics can be improved.

Moreover, in accordance with the semiconductor device according to the modified example of the third embodiment, since the fifth external heat sink and the sixth external heat sink are provided, the heat generated from the memory controller and the NAND flash memory can be dissipated to be separated, and thereby thermal dispersion characteristics can be further improved.

### FOURTH EMBODIMENT

### Configuration of Package Structure of Semiconductor Device

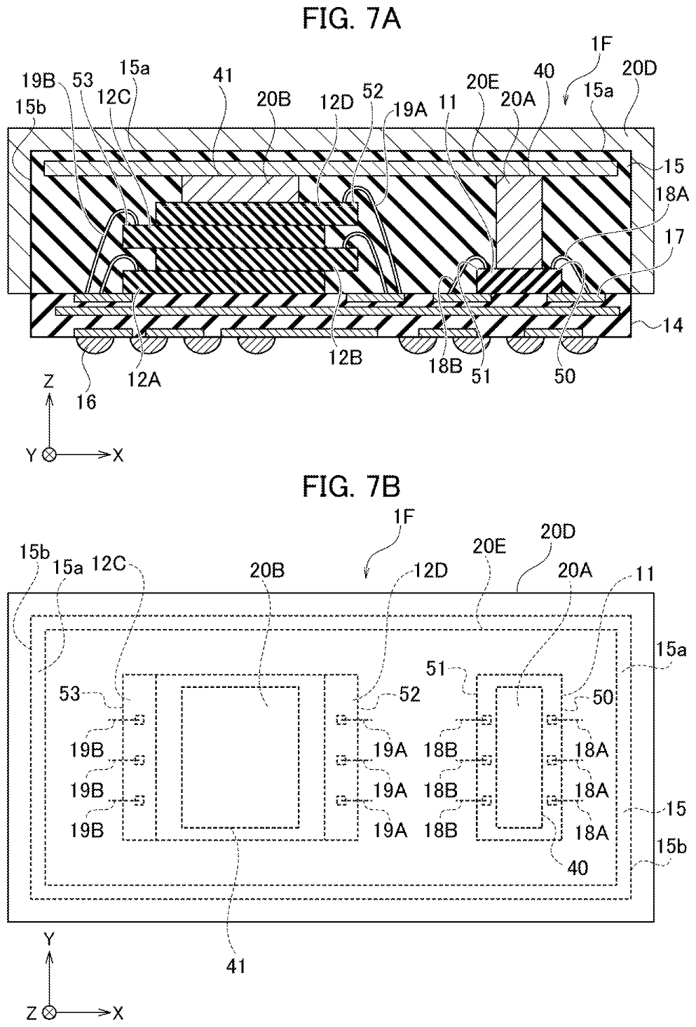

FIG. 7A is a cross-sectional diagram illustrating a semiconductor device 1F according to a fourth embodiment. FIG. 7B is a top view diagram illustrating the semiconductor device 1F according to the fourth embodiment.

As illustrated in FIG. 7A, the semiconductor device 1F according to the fourth embodiment is further includes, a fourth external heat sink 20D configured to cover the upper surface 15a and the side surfaces 15b of the first resin sealing body 15, and a first internal heat sink 20E disposed inside the first resin sealing body 15, with respect to the semiconductor device 1A according to the first embodiment. Since the rest of configuration is identical with that of the first embodiment, the duplicated description is omitted.

The first internal heat sink 20E is formed of, for example, a metal having a high coefficient of thermal conductivity. Specifically, copper (Cu), aluminum (Al), silver (Ag), gold (Au), or the like can be applied the metal.

As illustrated in FIG. 7A, the fourth external heat sink 20D is disposed in contact with the upper surface 15a and side surfaces 15b of the first resin sealing body 15.

As illustrated in FIGS. 7A and 7B, the first internal heat sink 20E is disposed in contact with the upper surface 40 of the first heat sink 20A and the upper surface 41 of the second heat sink 20B. Namely, the heat from the first heat sink 20A and the second heat sink 20B is dissipated mainly from the first internal heat sink 20E.

As illustrated in FIG. 7B, an area of the first internal heat sink 20E is disposed smaller than an area of the first resin sealing body 15 in planar view.

### Advantageous Effects of Fourth Embodiment

In accordance with the semiconductor device according to the fourth embodiment, the heat generated from the memory controller and the NAND flash memory can be appropriately dissipated respectively to the first heat sink and the second heat and sink, thereby thermal dispersion characteristics can be improved. Moreover, the heat from the first heat sink and the second heat sink can be appropriately dissipated to the first internal heat sink, and thereby thermal dispersion characteristics can be improved.

### MODIFIED EXAMPLE OF FOURTH EMBODIMENT

### Configuration of Package Structure of Semiconductor Device

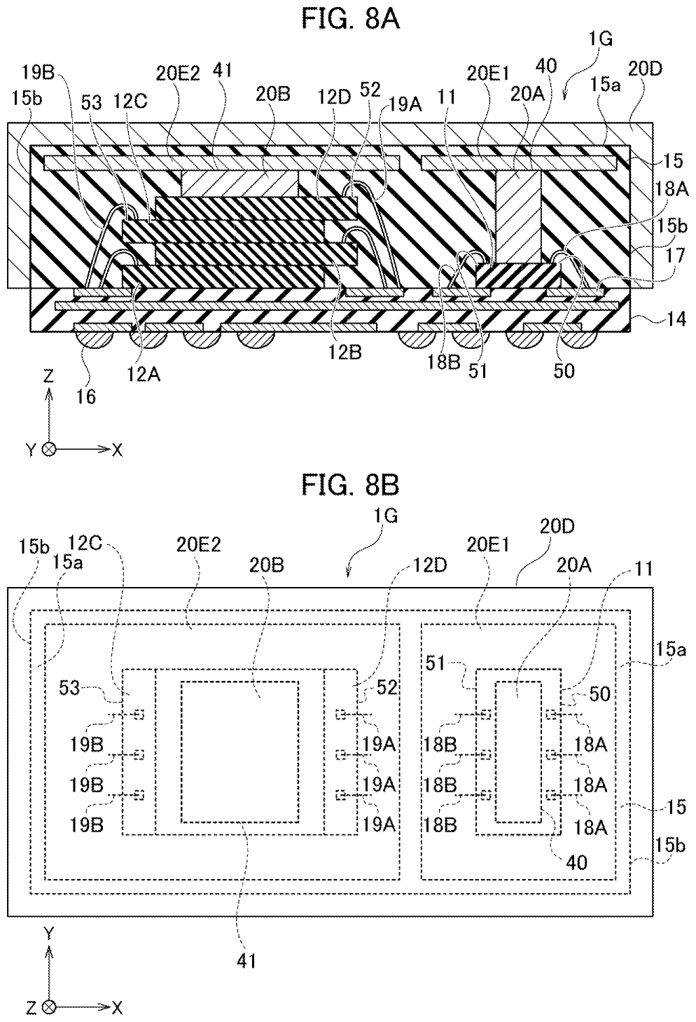

FIG. 8A is a cross-sectional diagram illustrating a semiconductor device 1G according to a modified example of the fourth embodiment. FIG. 8B is a top view diagram illustrating the semiconductor device 1G according to the modified example of the fourth embodiment.

As illustrated in FIG. 8A, the semiconductor device 1G according to the modified example of the fourth embodiment includes a second internal heat sink 20E1 and a third internal heat sink 20E2 each disposed inside the first resin sealing body 15, in contrast to the first internal heat sink 20E in the semiconductor device 1F according to the fourth embodiment. Since the rest of configuration is identical with that of the third embodiment, the duplicated description is omitted.

The second internal heat sink 20E1 and the third internal heat sink 20E2 are formed of, for example, a metal having a high coefficient of thermal conductivity. Specifically, copper (Cu), aluminum (Al), silver (Ag), gold (Au), or the like can be applied the metal.

As illustrated in FIGS. 8A and 8B, the second internal heat sink 20E1 is disposed in contact with the upper surface 40 of the first heat sink 20A. Namely, the heat from the first heat sink 20A is dissipated mainly from the second internal heat sink 20E1.

The third internal heat sink 20E2 is disposed in contact with the upper surface 41 of the second heat sink 20B.

As illustrated in FIG. 8B, The third internal heat sink 20E2 is disposed to be separated from the second internal heat sink 20E1. Namely, the heat from the second heat sink 20B is dissipated mainly from the third internal heat sink 20E2. An area of the third internal heat sink 20E2 may be disposed larger than that of the second internal heat sink 20E1 in planar view.

### Effects of Modified Examples of Fourth Embodiment

In accordance with the semiconductor device according to the modified example of the fourth embodiment, the heat generated from the memory controller and the NAND flash memory can be appropriately dissipated respectively to the first heat sink and the second heat sink, and thereby thermal dispersion characteristics can be improved.

Moreover, in accordance with the semiconductor device according to the modified example of the fourth embodiment, since the second internal heat sink and the third internal heat sink are provided, the heat generated from the memory controller 11 and the NAND flash memory 12 can be dissipated to be separated, and thereby thermal dispersion characteristics can be further improved.

### FIFTH EMBODIMENT

### Configuration of Package Structure of Semiconductor Device

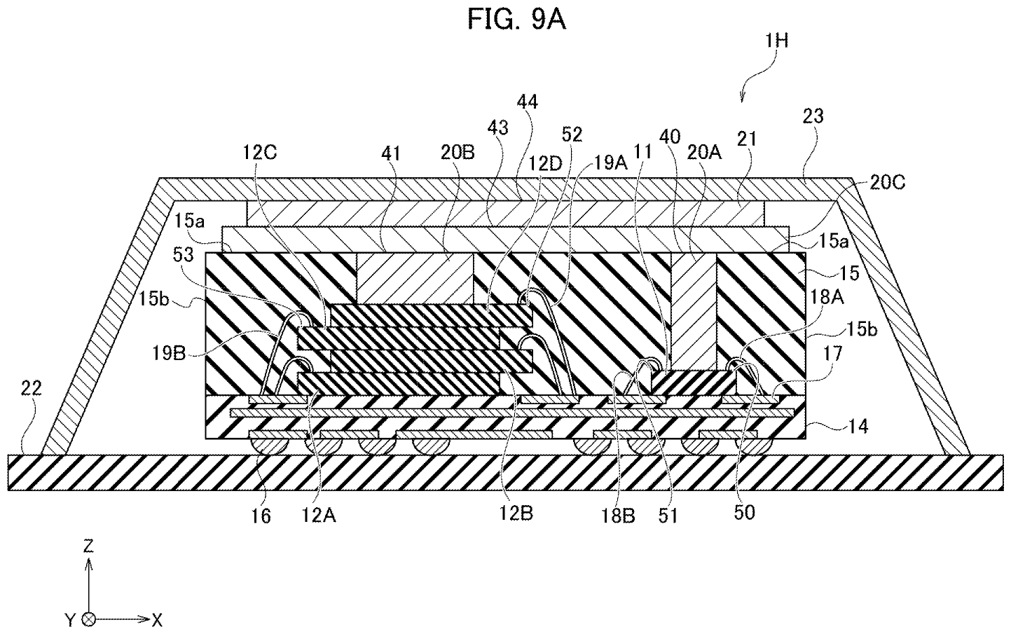

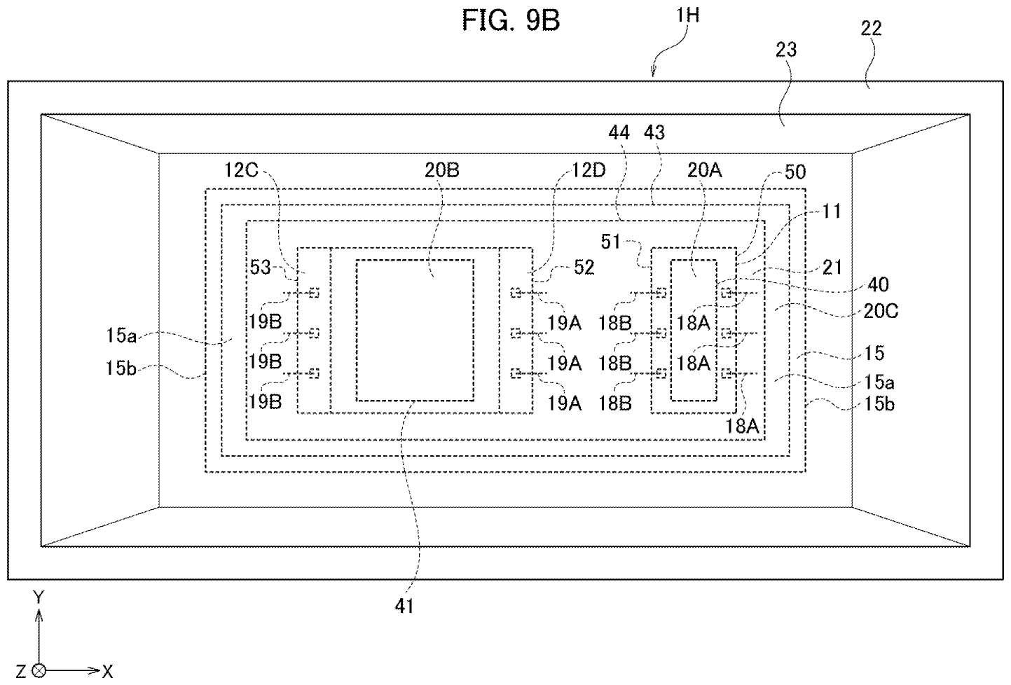

FIG. 9A is a cross-sectional diagram illustrating a semiconductor device 1H according to a fifth embodiment. FIG. 9B is a top view diagram illustrating the semiconductor device 1H according to the fifth embodiment.

As illustrated in FIG. 9A, the semiconductor device 1H according to the fifth embodiment further includes a mounting substrate 22, a thermal conductor 21, and a metal housing 23, with respect to the semiconductor device 1B according to the second embodiment. Since the rest of configuration is identical with that of the third embodiment, the duplicated description is omitted.

The mounting substrate 22 includes a multilayered wiring substrate. Although not illustrated, the mounting substrate 22 may include wirings. A mounting substrate 22 is electrically connected to solder balls 16 through the wirings provided in the mounting substrate 22.

The thermal conductor 21 can be produced from a thermal conductive paste having metal or metal oxide particles having a high coefficient of thermal conductivity. For example, metals having high coefficients of thermal conductivity, such as silver (Ag), copper (Cu), and aluminum (Al), can be applied to the thermal conductive paste. Alternatively, for example, metal oxides, such as an aluminium oxide (Al₂O₃), a magnesium oxide (MgO), and aluminium nitride (AlN), can be applied thereto. Alternatively, the thermal conductor 21 may be a thermally conductive sheet or thermally conductive grease.

As illustrated in FIG. 9A, the thermal conductor 21 is disposed on the first external heat sink 20C. The thermal conductor 21 is disposed in contact with an upper surface 43 of the first external heat sink 20C and a lower surface 44 of the metal housing 23. In the following description, a main surface of the metal housing 23 in contact with the thermal conductor 21 is referred to as the lower surface 44 of the metal housing 23.

The metal housing 23 is formed with a metal that shields electromagnetic waves. For example, alloy of copper (Cu) and beryllium (Be), an alloy of ferrum (Fe) and nickel (Ni), or the like can be applied thereto. Alternatively, copper (Cu), aluminum (Al), silver (Ag), gold (Au), or the like can be applied thereto. Specifically, for example, a noise shield or the like formed with a metal can be applied thereto.

As illustrated in FIG. 9B, the metal housing 23 is disposed, on the mounting substrate 22, so as to cover the first resin sealing body 15, the first external heat sink 20C, and the thermal conductor 21. Namely, the heat from the first heat sink 20A and the second heat sink 20B is dissipated mainly from the metal housing 23 through the first external heat sink 20C and the thermal conductor 21.

### Advantageous Effects of Fifth Embodiment

In accordance with the semiconductor device according to the fifth embodiment, the heat generated from the memory controller and the NAND flash memory can be appropriately dissipated respectively to the first heat sink and the second heat sink, and thereby thermal dispersion characteristics can be improved. Furthermore, the heat from the first heat sink and the second heat sink can be appropriately dissipated to the metal housing through the first external heat sink and the thermal conductor, and thereby thermal dispersion characteristics can be further improved.

### MODIFIED EXAMPLE OF FIFTH EMBODIMENT

### Configuration of Package Structure of Semiconductor Device

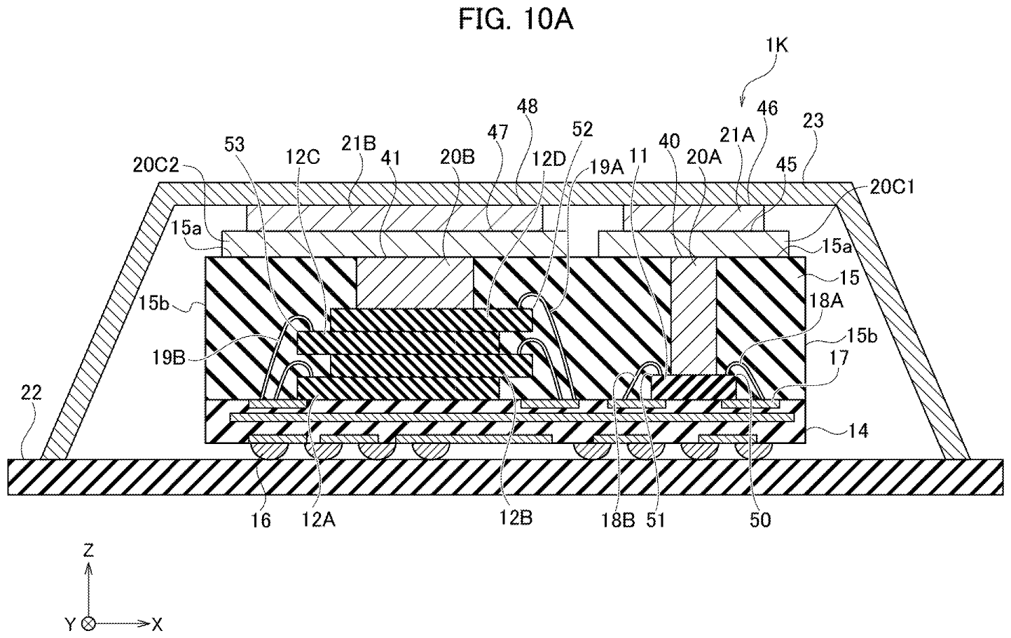

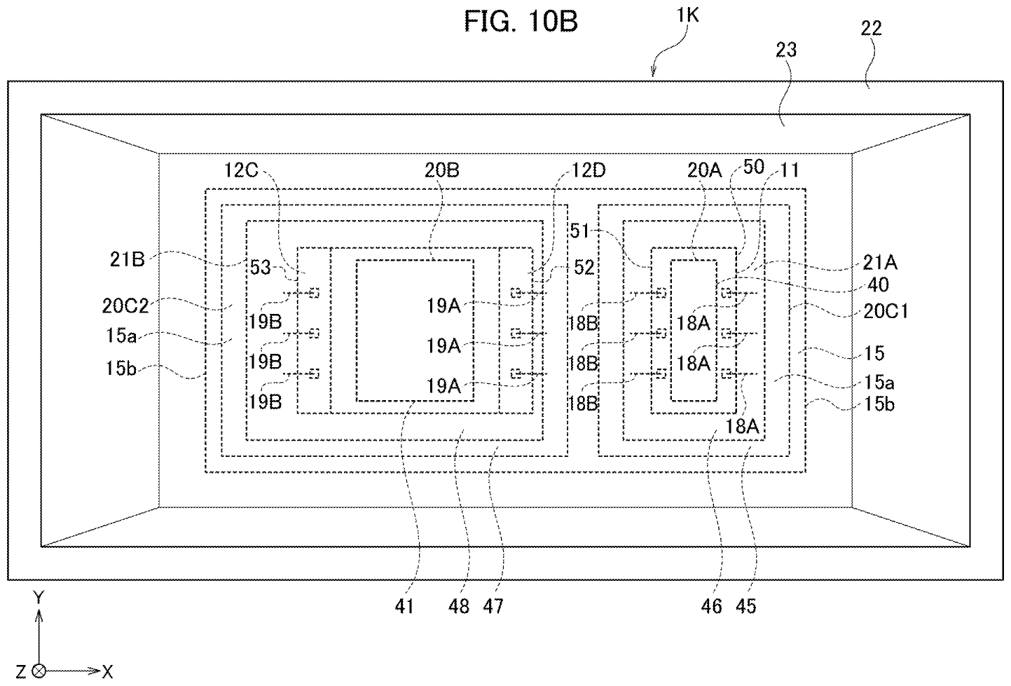

FIG. 10A is a cross-sectional diagram illustrating a semiconductor device 1K according to a modified example of the fifth embodiment. FIG. 10B is a top view diagram illustrating the semiconductor device 1K according to the modified example of the fifth embodiment.

As illustrated in FIG. 10A, the semiconductor device 1K according to the modified example of the fifth embodiment includes a second external heat sink 20C1 and a third external heat sink 20C2, in contrast to the first external heat sink 20C in the semiconductor device 1H according to the fifth embodiment. Moreover, the semiconductor device 1K includes a thermal conductor 21A and a thermal conductor 21B, in contrast to the thermal conductor 21 in the semiconductor device 1H according to the fifth embodiment. Since the rest of configuration is identical with that of the fifth embodiment, the duplicated description is omitted.

The second external heat sink 20C1 and the third external heat sink 20C2 are formed of, for example, a metal having a thermal high coefficient of conductivity. Specifically, copper (Cu), aluminum (Al), silver (Ag), gold (Au), or the like can be applied thereto.

The thermal conductor 21A and the thermal conductor 21B can be produced from a thermal conductive paste having metal or metal oxide particles having a high coefficient of thermal conductivity, similar to the thermal conductor 21. Alternatively, the thermal conductor 21A and the thermal conductor 21B may be a thermally conductive sheet or thermally conductive grease.

As illustrated in FIG. 10A, the second external heat sink 20C1 is disposed in contact with the upper surface 40 of the first heat sink 20A. Namely, the heat from the first heat sink 20A is dissipated mainly from the second external heat sink 20C1.

The third external heat sink 20C2 is disposed in contact with the upper surface 41 of the second heat sink 20B. Namely, the third external heat sink 20C2 is disposed to be separated from the second external heat sink 20C1, as illustrated in FIG. 10B. The heat from the second heat sink 20B is dissipated mainly from the third external heat sink 20C2.

As illustrated in FIG. 10A, the thermal conductor 21A is provided on the second external heat sink 20C1. The thermal conductor 21A is disposed in contact with the upper surface 45 of the second external heat sink 20C1 and a lower surface 46 of the metal housing 23. Namely, the heat from the second external heat sink 20C1 is dissipated mainly from the metal housing 23 through the thermal conductor 21A.

As illustrated in FIG. 10A, the thermal conductor 21B is provided on the third external heat sink 20C2. The thermal conductor 21B is disposed in contact with a upper surface 47 of the third external heat sink 20C2 and a lower surface 48 of the metal housing 23. Namely, the thermal conductor 21B is disposed to be separated from the thermal conductor 21A, as illustrated in FIG. 10B. Namely, the heat from the third external heat sink 20C2 is dissipated mainly from the metal housing 23 through the thermal conductor 21B.

### Advantageous Effects of Modified Example of Fifth Embodiment

In accordance with the semiconductor device according to the modified example of the fifth embodiment, the heat generated from the memory controller and the NAND flash memory can be appropriately dissipated respectively to the first heat sink and the second heat sink, and thereby thermal dispersion characteristics can be improved.

Moreover, in accordance with the semiconductor device according to the modified example of the fifth embodiment, since the second external heat sink and the third external heat sink are provided, the heat generated from the memory controller and the NAND flash memory can be dissipated to be separated, and thereby thermal dispersion characteristics can be further improved. Furthermore, the heat from the second external heat sink and the third external heat sink can be appropriately dissipated mainly to the metal housing through the thermal conductor, and thereby thermal dispersion characteristics can be further improved.

### SIXTH EMBODIMENT

### Configuration of Package Structure of Semiconductor Device

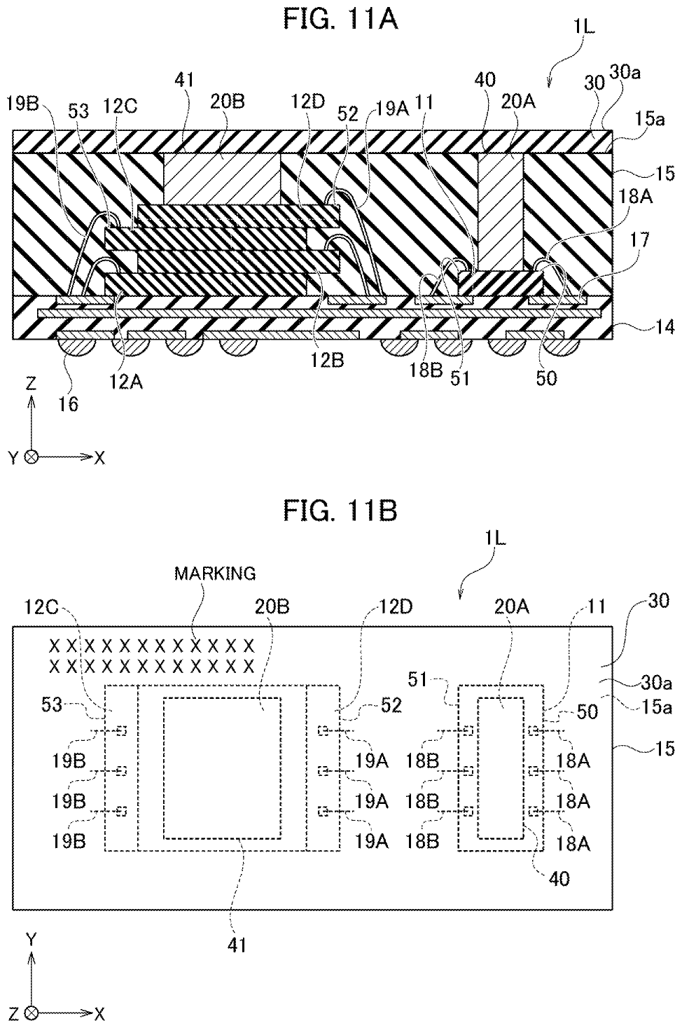

FIG. 11A is a cross-sectional diagram illustrating a semiconductor device 1L according to a sixth embodiment. FIG. 11B is a top view diagram illustrating the semiconductor device 1L according to the sixth embodiment.

As illustrated in FIG. 11A, the semiconductor device 1L according to the sixth embodiment further includes a second resin sealing body 30, with respect to the semiconductor device 1A according to the first embodiment. Since the rest of configuration is identical with that of the first embodiment, the duplicated description is omitted.

As illustrated in FIG. 11B, the second resin sealing body 30 seals to cover the upper surface 15a of the first resin sealing body 15 and the first and the second heat sinks 20A, 20B. Namely, the heat generated from the memory controller 11 is dissipated mainly from the first heat sink 20A. The heat generated from the memory controller 11 is dissipated mainly from the first heat sink 20A. Alternatively, between the first resin sealing body 15 and the second resin sealing body 30, it may be further provided with an external heat sink, a thermal conductor, and a metal housing disposed on the upper portion of the first resin sealing body 15 as in the modified examples of the second to fifth embodiments. Alternatively, it may be further provided with an internal heat sink disposed inside the first resin sealing body 15.

The second resin sealing body 30 may be, for example, a mixture of a thermosetting resin, which is an epoxy resin, and silica. Alternatively, the second resin sealing body 30 may be an epoxy resin containing carbon black, or the like.

As illustrated in FIG. 11B, product information, such as a company name, a product number, a fabrication date, a fabrication factory, and the like, is marked on the upper surface 30a of the second resin sealing body 30, for example, by laser light radiation.

As illustrated in FIG. 11B, the marking is engraved at a location other than the locations of the first heat sink 20A and the second heat sink 20B in planar view.

### Advantageous Effects of Sixth Embodiment

In accordance with the semiconductor device according to the sixth embodiment, the heat generated from the memory controller and the NAND flash memory can be appropriately dissipated respectively to the first heat sink and the second heat and sink, thereby thermal dispersion characteristics can be improved.

Moreover, in accordance with the semiconductor device according to the sixth embodiment, since the marking is engraved at a location other than the locations of the first heat sink and the second heat sink in planar view, the heat generated from the memory controller and the NAND flash memory can be appropriately dissipated respectively to the first heat sink and the second heat sink, and thereby thermal dispersion characteristics can be improved, while reducing a damage due to the laser light radiation.

### ELECTRONIC DEVICE

A configuration of an electronic device 2 in which the semiconductor device 1 according to embodiments is mounted will now be described.

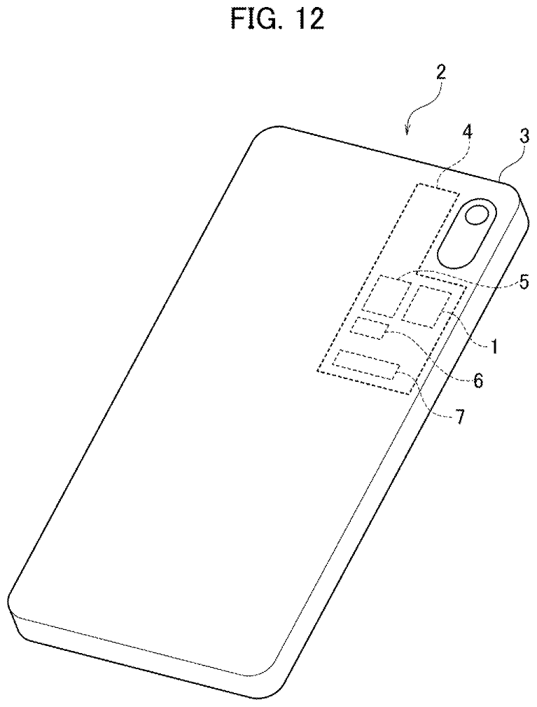

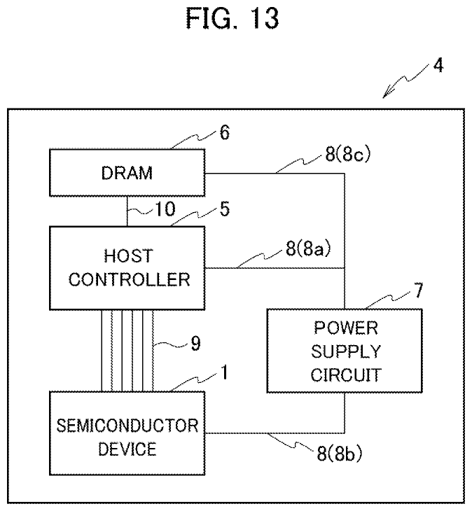

FIG. 12 is a configuration diagram illustrating the electronic device 2 in which the semiconductor device 1 according to embodiments is mounted. FIG. 13 is a block diagram illustrating a circuit substrate 4 of the electronic device 2.

The electronic device 2 includes a housing 3, as illustrated in FIG. 12. The housing 3 houses the circuit substrate 4. The circuit substrate 4 includes a semiconductor device 1, a host controller 5, a DRAM 6, which is an example of a volatile memory, and a power supply circuit 7. More specifically, the electronic devices 2 may be, for example, a smart phone, a tablet-type device, or a mobile terminal. Actually, the electronic devices 2 is not limited to such examples. In this embodiment, the electronic device 2 is described as a smart phone.

Namely, the semiconductor device 1 according to the first to sixth embodiments can be applied to the electronic device 2.

As illustrated in FIG. 13, the power supply circuit 7 is provided on the circuit substrate 4. The power supply circuit 7 is connected to the semiconductor device 1, the host controller 5, and the DRAM 6 respectively through power supply lines 8 (8a, 8b, 8c). The power supply circuit 7 supplies a power supply voltage to the host controller 5 through the power supply line 8a. Moreover, the power supply circuit 7 supplies the power supply voltage to the semiconductor device 1 through the power supply line 8b. Similarly, the power supply circuit 7 supplies the power supply voltage to the DRAM 6 through the power supply line 8c.

For example, a plurality of signal lines 9 are provided between the semiconductor device 1 and the host controller 5. The semiconductor device 1 is functioned as a storage device for the electronic device 2. The semiconductor device 1 exchanges signals with the host controllers 5 through the plurality of signal lines 9. The semiconductor device 1 may have, for example, a multi-chip package configured with a plurality of memory chip.

For example, a signal line 10 is provided between the DRAM 6 and the host controller 5. The DRAM 6 temporarily stores data and the like used during program execution processing in the host controller 5 and functions as temporary memory and the like used as a work area. The DRAM 6 exchanges signals with the host controllers 5 through the signal line 10.

The host controller 5 is an integrated circuit configured to control the overall operation for the electronic device 2 including the semiconductor device 1. The host controller 5 may also include, for example, a south bridge.

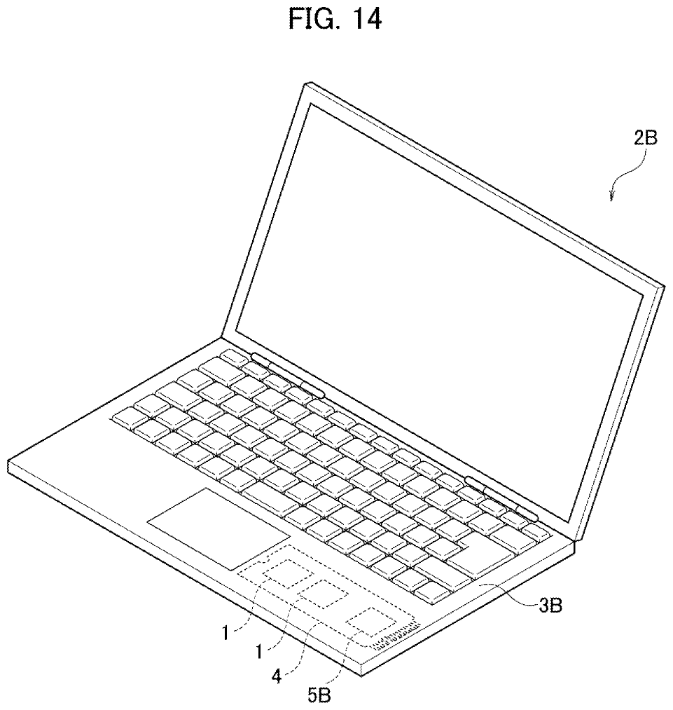

FIG. 14 is a configuration diagram illustrating an electronic device 2B in which the semiconductor device 1 according to embodiments is mounted.

The electronic device 2B includes a housing 3B, as illustrated in FIG. 14. The housing 3B houses a circuit substrate 4. The circuit substrate 4 includes the semiconductor device 1 and a host controller 5B. Specifically, the electronic device 2B may be, for example, a desktop or laptop personal computer.

Namely, the semiconductor device 1 according to the first to sixth embodiments can be applied to the electronic device 2B.

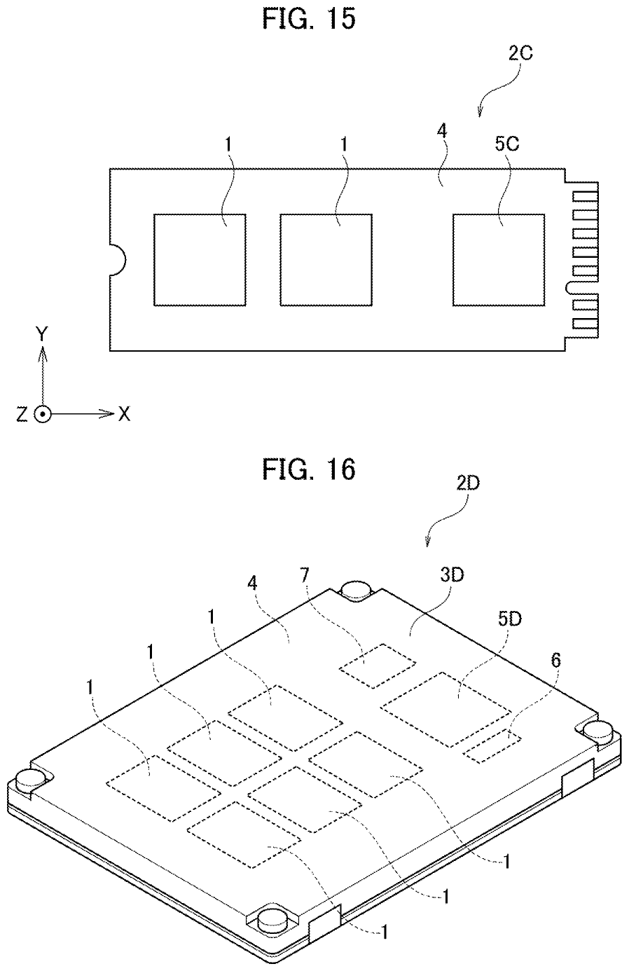

FIG. 15 is a configuration diagram illustrating an electronic device 2C in which the semiconductor device 1 according to embodiments is mounted.

The electronic device 2C includes a circuit substrate 4, as illustrated in FIG. 15. The circuit substrate 4 includes the semiconductor device 1 and a host controller 5C. Specifically, the electronic device 2C may be, for example, M.2 Solid State Drive (M.2 SSD), which is an example of a storage device (storage).

Namely, the semiconductor device 1 according to the first to sixth embodiments can be applied to the electronic device 2C.

FIG. 16 is a configuration diagram illustrating an electronic device 2D in which the semiconductor device 1 according to embodiments is mounted.

The electronic device 2D includes a housing 3D, as illustrated in FIG. 16. The housing 3D houses a circuit substrate 4. The circuit substrate 4 includes the semiconductor device 1, a host controller 5D, a DRAM 6, and a power supply circuit 7. Specifically, the electronic device 2D may be, for example, an SSD.

Namely, the semiconductor device 1 according to the first to sixth embodiments can be applied to the electronic device 2D.

While certain embodiments have been described, these embodiments have been presented by way of examples only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a controller disposed on the substrate;
a nonvolatile memory disposed on the substrate to be separated from the controller;
a first heat sink disposed in contact with an upper surface of the controller;
a second heat sink disposed in contact with an upper surface of the nonvolatile memory; and
a first resin sealing body sealing the controller, the nonvolatile memory, the first heat sink, and the second heat sink, wherein
the first heat sink and the second heat sink are exposed on at least one surface selected from the group consisting of an upper surface and a side surface of the first resin sealing body.

2. The semiconductor device according to claim 1, wherein
a thickness of the first heat sink is thicker than a thickness of the second heat sink.

3. The semiconductor device according to claim 1, further comprising:
a wiring disposed in the substrate;
a bonding wire electrically connecting the wiring to the controller and the nonvolatile memory, on the substrate; and
a solder ball electrically connected to the wiring, wherein
the controller includes a first one end, and a first other end opposite to the first one end, and
the nonvolatile memory includes a second one end, and a second other end opposite to the second one end, wherein
the bonding wire includes
a first bonding wire electrically connected to the first one end and a second bonding wire electrically connected to the first other end, on the controller, and
a third bonding wire electrically connected to the second one end and a fourth bonding wire electrically connected to the second other end, on the nonvolatile memory, wherein
the first heat sink is disposed between the first bonding wire and the second bonding wire, on the controller, in planar view, and
the second heat sink is disposed between the third bonding wire and the fourth bonding wire, on the nonvolatile memory, in planar view.

4. The semiconductor device according to claim 1, wherein
an area of the second heat sink exposed on the upper surface of the first resin sealing body is larger than an area of the first heat sink exposed on the upper surface of the first resin sealing body.

5. The semiconductor device according to claim 2, wherein
an area of the second heat sink exposed on the upper surface of the first resin sealing body is larger than an area of the first heat sink exposed on the upper surface of the first resin sealing body.

6. The semiconductor device according to claim 3, wherein
a first external heat sink disposed, on the upper surface on the first resin sealing body, to be in contact with the first heat sink and the second heat sink and to cover the first heat sink and the second heat sink.

7. The semiconductor device according to claim 6, wherein
an area of an upper surface of the first external heat sink is smaller than an area of the upper surface of the first resin sealing body.

8. The semiconductor device according to claim 3, further comprising:
a second external heat sink disposed to be in contact with the first heat sink and to cover the first heat sink, on the first resin sealing body; and
a third external heat sink disposed to be in contact with the second heat sink and to cover the second heat sink, on the first resin sealing body.

9. The semiconductor device according to claim 8, wherein
an area of an upper surface of the third external heat sink is larger than an area of an upper surface of the second external heat sink.

10. The semiconductor device according to claim 1, wherein
an area of the second heat sink exposed on the upper surface of the first resin sealing body is larger than an area of the first heat sink exposed on the side surface of the first resin sealing body.

11. The semiconductor device according to claim 2, wherein
an area of the second heat sink exposed on the upper surface of the first resin sealing body is larger than an area of the first heat sink exposed on the side surface of the first resin sealing body.

12. The semiconductor device according to claim 10, further comprising:
a fourth external heat sink disposed to be in contact with the first heat sink and the second heat sink and to cover the first heat sink and the second heat sink, on the upper surface and the side surface on the first resin sealing body.

13. The semiconductor device according to claim 10, further comprising:
a fifth external heat sink disposed to be in contact with the first heat sink and to cover the first heat sink, on the first resin sealing body; and
a sixth external heat sink disposed to be in contact with the second heat sink and to cover the second heat sink, on the first resin sealing body.

14. The semiconductor device according to claim 6, further comprising:
a mounting substrate electrically connected to the solder ball;
a metal housing disposed on the mounting substrate; and
a thermal conductor disposed on the first external heat sink and being in contact with the first external heat sink and the metal housing.

15. The semiconductor device according to claim 8, further comprising:
a mounting substrate electrically connected to the solder ball;
a metal housing disposed on the mounting substrate; and
a thermal conductor disposed on the second external heat sink and the third external heat sink and being in contact with the second external heat sink, the third external heat sink, and the metal housing.

16. The semiconductor device according to claim 1, further comprising:
a second resin sealing body stacked on the first resin sealing body to cover the first resin sealing body, the first heat sink, and the second heat sink.

17. The semiconductor device according to claim 16, wherein
a marking is engraved on an upper surface of the second resin sealing body other than a location of the first heat sink and the second heat sink.

18. The semiconductor device according to claim 12, wherein
the fourth external heat sink contains an element selected from the group consisting of copper (Cu), aluminum (Al), silver (Ag), and from a gold (Au).

19. An electronic device comprising:
a circuit substrate;
the semiconductor device according to claim 1 mounted on the circuit substrate; and
a host controller mounted on the circuit substrate, the host controller configured to control the semiconductor device.

20. The electronic device according to claim 19, further comprising:
a volatile memory mounted on the circuit substrate, the volatile memory temporarily storing data for the host controller;
a power supply circuit mounted on the circuit substrate, the power supply circuit configured to supply electric power to the host controller, the semiconductor device, and the volatile memory; and
a housing for housing the circuit substrate.
